(19) United States
(12) Patent Application Publication
(10) Pub. No.: US 2012/0097945 A1
(43) Pub. Date: Apr. 26, 2012

(54) POLYCRYSTALLINE METAL-BASED LED HEAT DISSIPATING STRUCTURE AND METHOD FOR MANUFACTURING THE SAME

(76) Inventor: YAO-LONG WEN, Taipei (TW)

(21) Appl. No.: 12/908,885

(22) Filed: Oct. 21, 2010

(51) Int. Cl. H01L 33/48; H01L 33/16

(52) U.S. Cl. 257/49; 438/26; 257/E33.056; 257/E33.075; 257/E33.003

(57) ABSTRACT

A polycrystalline metal-based LED heat dissipating structure includes a composite substrate, an insulated heat conducting layer, printed circuit layer, electric and heat conducting layer, and a polycrystalline metal-based LED. The composite substrate and the printed circuit layer are linked by the insulated heat conducting layer. The printed circuit layer and the polycrystalline metal-based LED are linked by the electric and heat conducting layer. Through the above structure, the life time of the polycrystalline metal-based LED will be prolonged and the light decadency will be prevented.

### FIELD OF THE INVENTION

The present invention relates to heat dissipating structure and the method of manufacture, and particular to a polycrystalline metal-based LED heat dissipating structure and the method of manufacture.

### DESCRIPTION OF THE PRIOR ART

LED lights are taking the place of the conventional lights for the environment concern. For satisfying the requirements of the market, polycrystalline LED is becoming a main stream of the industry. However, the heat dissipating problem and uneven heat dissipation still cause light decadency of LED and shortage of lifetime.

### SUMMARY OF THE PRESENT INVENTION

Accordingly, the inventor of the present invention endeavored to improve the heat dissipating structure of prior LED.

The primary object of the present invention is to provide a polycrystalline metal-based LED heat dissipating structure and the method of manufacture for prolonging the lifetime of the polycrystalline metal-based LED and for preventing a light decadency.

To achieve the above object, the method of manufacture of the polycrystalline metal-based LED heat dissipating structure includes the following steps.

(A) A printed circuit layer is arranged onto a composite substrate;

(B) A polycrystalline metal-based LED is arranged to the printed circuit layer;

(C) The printed circuit layer and the polycrystalline metal-based LED are connected by a conducting wire.

The polycrystalline metal-based LED heat dissipating structure consists of the composite substrate, printed circuit layer, electric and heat conducting layer, polycrystalline metal-based LED, and the insulated heat conducting layer. The composite substrate and the printed circuit layer are linked by the insulated heat conducting layer. The printed circuit layer and the polycrystalline metal-based LED are linked by the electric and heat conducting layer.

Through the present invention, the heat generated by the polycrystalline metal-based LED will be transversely dissipated quickly and evenly through the copper printed circuit layer. The heat will also be dissipated quickly and equally through composite substrate, the three directions heat dissipation will achieve quick heat dissipation. By the equally heat dissipation, the polycrystalline metal-based LED also have equal Thermoelectric Effect so that a life time is prolonged and a light decadency will be prevented.

### DETAILED DESCRIPTION OF THE INVENTION

In order that those skilled in the art can further understand the present invention, a description will be provided in the following in details. However, these descriptions and the appended drawings are only used to cause those skilled in the art to understand the objects, features, and characteristics of the present invention, but not to be used to confine the scope and spirit of the present invention defined in the appended claims.

A method for manufacturing a polycrystalline metal-based LED heat dissipating structure includes the following steps.

(A) A printed circuit is arranged onto a composite substrate;

(B) The polycrystalline metal-based LED is arranged to the printed circuit;

(C) A conducting wire is electrically connected to the printed circuit.

Referring to FIG. 1.1, the step A of the present invention is illustrated. A printed circuit layer 2 is arranged onto a composite substrate 1. An insulated heat-conducted layer 5 is arranged between the composite substrate 1 and the printed circuit layer 2.

Referring to FIG. 1.2, the step B of the present invention is illustrated. A polycrystalline metal-based LED 4 is arranged to the printed circuit layer 2 with an electric and heat conducted layer 3 between by hot melting method such as high frequency wave or super sonic wave.

Referring to FIG. 1.3, the step C of the present invention is illustrated. The polycrystalline metal-based LED 4 combined to the printed circuit layer 2 is connected by a conducting wire 41 The polycrystalline metal-based LED 4 is arranged onto the printed circuit layer 2 with equal heat dissipation area. The electric and heat conducting layer 3 is made of material of silver gel or solder. The composite substrate 1 is made of one of a complex graphite or ceramic. The insulated heat conducting layer 5 is mad of glass fiber.

Referring to FIGS. 2 and 1.3, the present invention consists of the composite substrate 1, printed circuit layer 2, electric and heat conducting layer 3, polycrystalline metal-based LED 4, and the insulated heat conducting layer 5. The composite substrate 1 and the printed circuit layer 2 are linked by the insulated heat conducting layer 5. The printed circuit layer 2 and the polycrystalline metal-based LED 4 are linked by the electric and heat conducting layer 3. The polycrystalline metal-based LED 4 and the printed circuit layer 2 are connected by the conducting wire 41.

Referring to FIGS. 3 and 4, the present invention consists of the composite substrate 1, printed circuit layer 2, electric and heat conducting layer 3, polycrystalline metal-based LED 4, and the insulated heat conducting layer 5. The composite substrate 1 and the printed circuit layer 2 are linked by the insulated heat conducting layer 5. The printed circuit layer 2 and the polycrystalline metal-based LED 4 are linked by the electric and heat conducting layer 3. The polycrystalline metal-based LED 4 and the printed circuit layer 2 are connected by the conducting wire 41. The polycrystalline metal-based LED 4 is arranged onto the printed circuit layer 2 with equal heat dissipation area. With reference to FIG. 3, the polycrystalline metal-based LEDs 4 are arranged with equal heat dissipating area of copper printed circuit layer 2 so that the polycrystalline metal-based LEDs 4 have the same initial heat dissipating area. The heat generated by the polycrystalline metal-based LED 4 will be transversely dissipated quickly and evenly through the copper printed circuit layer 2.

Referring to FIG. 4, the heat generated by the polycrystalline metal-based LED 4 will also be dissipated quickly and equally through composite substrate 1, the 3 directions heat dissipation including the large area of copper printed circuit layer 2 will achieve quick heat dissipation. By the equally heat dissipation, the polycrystalline metal-based LEDs 4 also have equal Thermoelectric Effect.

The present invention has the following advantages.

1. The polycrystalline metal-based LEDs are arranged with equal heat dissipating area of copper printed circuit layer so that the polycrystalline metal-based LEDs have the same initial heat dissipating area. The heat generated by the polycrystalline metal-based LEDs will be transversely dissipated quickly and evenly through the copper printed circuit layer.

2. The heat generated by the polycrystalline metal-based LED will be dissipated quickly and equally through complex graphite substrate, the 3 directions heat dissipation will achieve quick heat dissipation. By the equal heat dissipation, the polycrystalline metal-based LEDs also have equal Thermoelectric Effect so that a life time thereof is prolonged and the light decadency will be prevented.

The present invention is thus described, it will be obvious that the same may be varied in many ways. Such variations are not to be regarded as a departure from the spirit and scope of the present invention, and all such modifications as would be obvious to one skilled in the art are intended to be included within the scope of the following claims.

### BRIEF DESCRIPTION OF THE DRAWINGS

FIG. 1.1 is a schematic view showing the step A of the present invention.

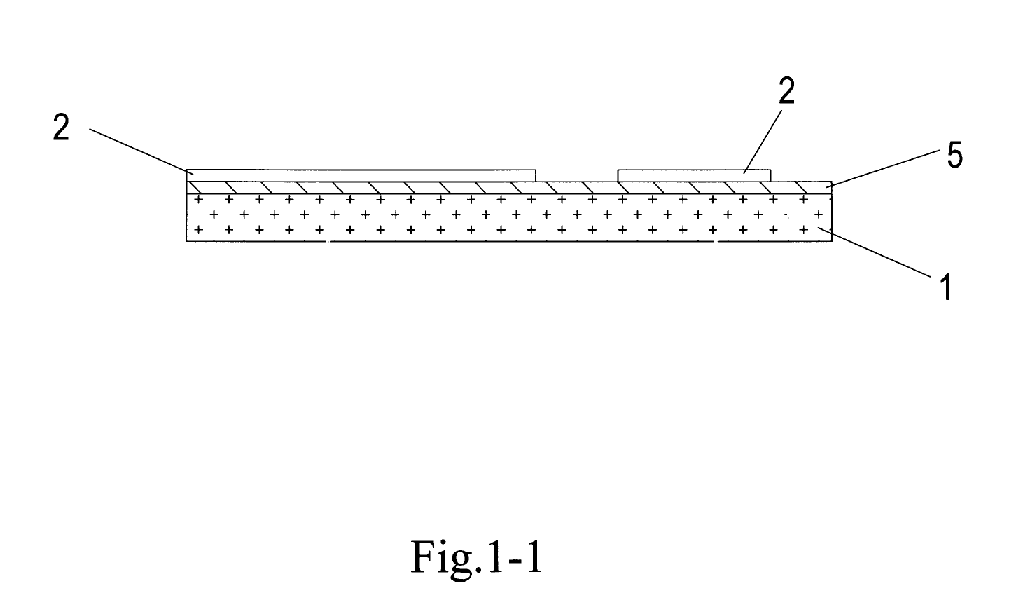

FIG. 1.2 is a schematic view showing the step B of the present invention.

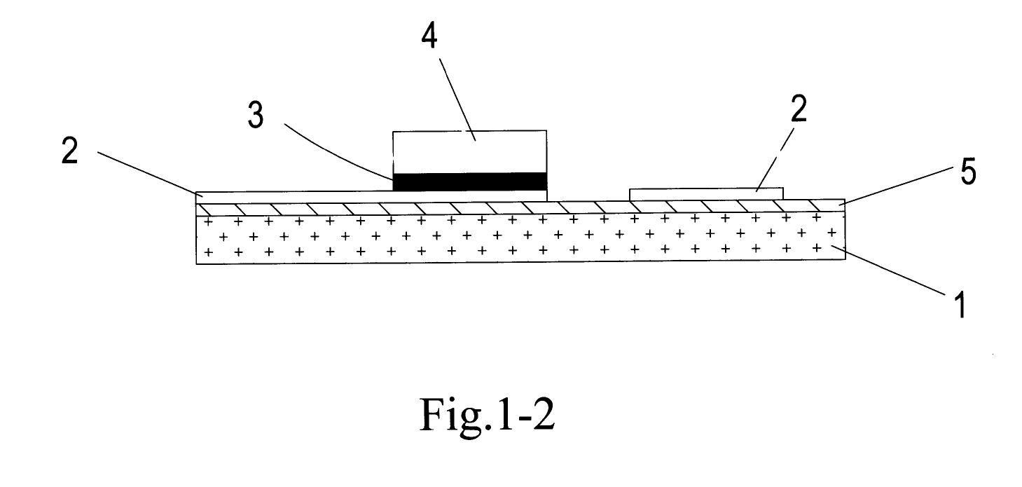

FIG. 1.3 is a schematic view showing the step C of the present

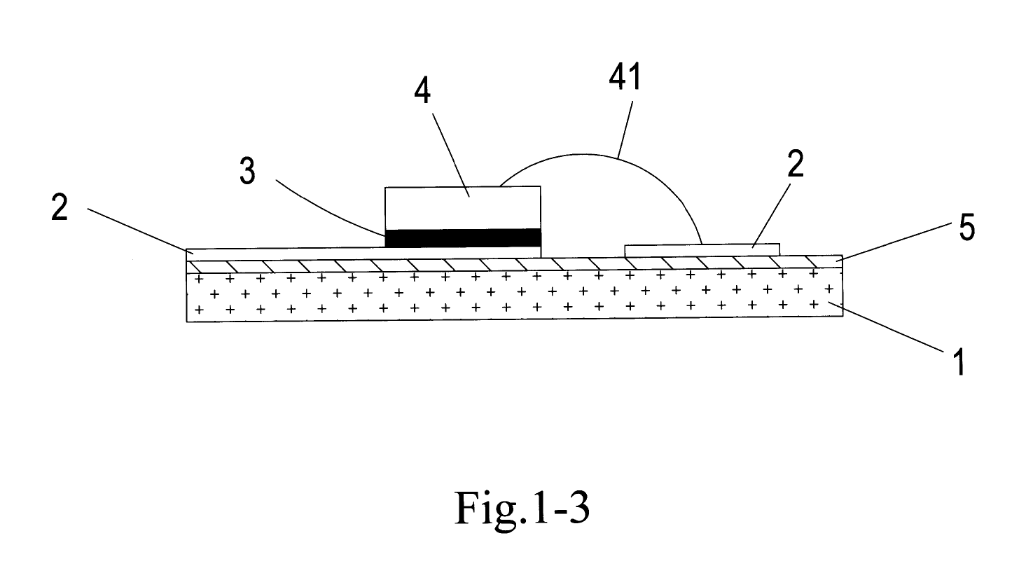

FIG. 2 is an exploded view of the present invention.

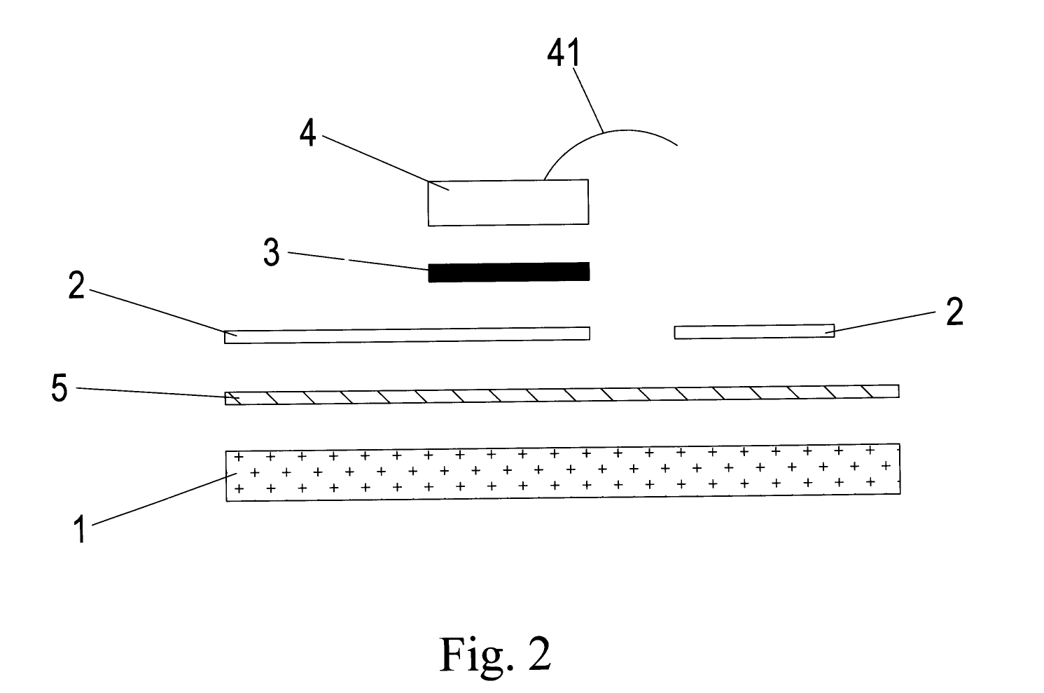

FIG. 3 is a top view of the present invention.

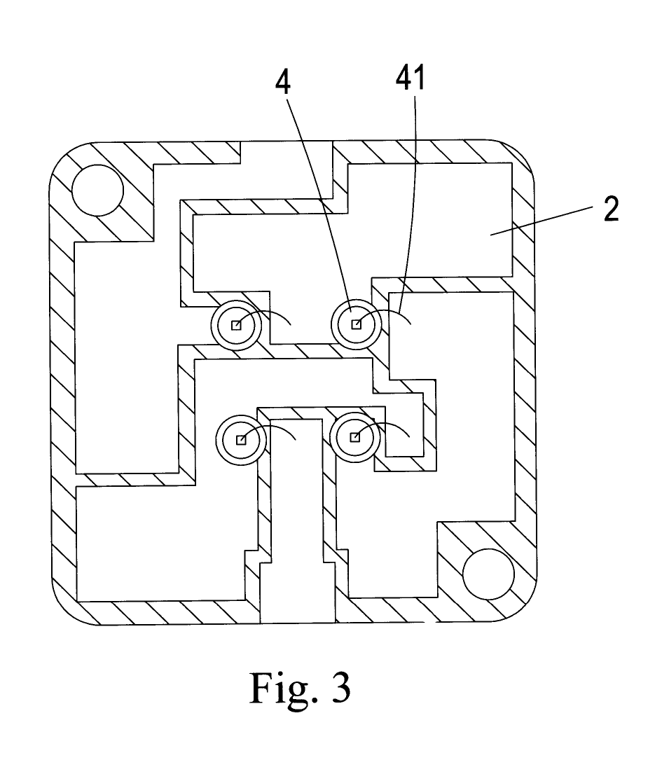

FIG. 4 is a schematic view showing the heat dissipation of the present invention.

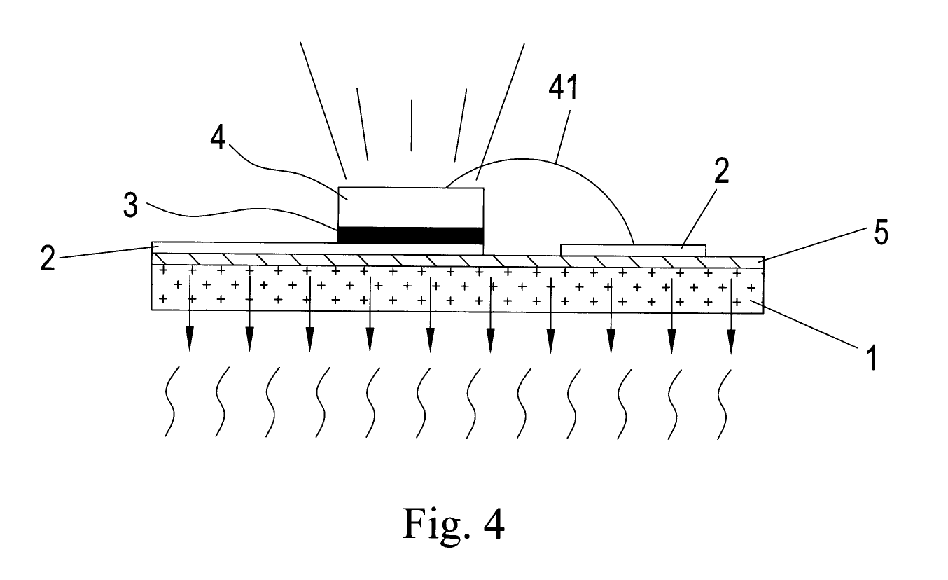

What is claimed is:

1. A method for manufacturing a polycrystalline metal-based LED heat dissipating structure comprising:
(A) arranging a printed circuit layer onto a composite substrate;
(B) arranging a polycrystalline metal-based LED to the printed circuit layer;
(C) connecting the printed circuit layer and the polycrystalline metal-based LED by a conducting wire.

2. The method for manufacturing a polycrystalline metal-based LED heat dissipating structure as claimed in claim 1, wherein the composite substrate and the polycrystalline metal-based LED are arranged by hot melting method.

3. The method for manufacturing a polycrystalline metal-based LED heat dissipating structure as claimed in claim 2, wherein the hot melting method is performed by one of a high frequency wave and super sonic wave.

4. The method for manufacturing a polycrystalline metal-based LED heat dissipating structure as claimed in claim 3, wherein the composite substrate is made of one of a complex graphite and ceramic.

5. The method for manufacturing a polycrystalline metal-based LED heat dissipating structure as claimed in claim 4, wherein the insulated heat conducting layer is made of glass fiber.

6. The method for manufacturing a polycrystalline metal-based LED heat dissipating structure as claimed in claim 5, wherein the electric and heat conducting layer is one of a silver gel and solder.

7. A polycrystalline metal-based LED heat dissipating structure comprising:
a printed circuit layer arranged on a composite substrate;
a polycrystalline metal-based LED arranged to the printed circuit layer by an electric and heat conducting layer.

8. The polycrystalline metal-based LED heat dissipating structure as claimed in claim 7, wherein the composite substrate and the printed circuit layer are linked by an insulated heat conducting layer.

9. The polycrystalline metal-based LED heat dissipating structure as claimed in claim 8, wherein the polycrystalline metal-based LED is arranged to the printed circuit layer evenly with equal heat dissipation area.
